(19) United States
(12) Patent Application Publication
(10) Pub. No.: US 2001/0050332 A1
(43) Pub. Date: Dec. 13, 2001

(54) Imagining device comprising a matrix of photodetectors, a corresponding spectroscopy system and a corresponding imaging method

(75) Inventor: Juichiro Ukon, Paris (FR)

Correspondence Address: YOUNG & THOMPSON, 745 SOUTH 23RD STREET 2ND FLOOR, ARLINGTON, VA, 22202

(73) Assignee: JOBIN YVON S.A.

(21) Appl. No.: 09/879,104

(22) Filed: Jun. 13, 2001

(30) Foreign Application Priority Data
Jun. 13, 2000 (FR) 0007527

(51) Int. Cl. H01L 27/00

(52) U.S. Cl. 250/208.1

(57) ABSTRACT

An imaging device and method, as well as a spectroscopy system. The imaging device includes a line-column matrix (1) of photodetectors (4), each of the photodetectors having a CMOS-type pixel (2) and a amplifier (3) with a gain. It also comprises gain control elements, capable of fixing the gains individually for each of the photodetectors. The imaging device is useful in spectroscopy, in particular for atomic emission.

This invention relates to an imaging device comprising a matrix of photodetectors, as well as a corresponding spectroscopy system and a corresponding imaging method.

It is easy to do ICP technology spectroscopy using a CCD-type photodetector matrix. It has also been suggested using a CID-type photodetector matrix, which advantageously enables direct addressing and non-destructive playback.

Besides, photodetector matrixes based on a CMOS technology have been implemented. Each photodetector then includes a CMOS-type pixel and an amplifier with a gain. This arrangement is divulged for example in the article ‘Active-pixel CMOS sensors improve their image of the review Laser Focus World, July 1999, PAGES 111-114. Such photodetector matrixes are known for offering various advantages, notably non-destructive playback, random access, high tolerance to radiations, low consumption and self-synchronisation.

However, the gain deviations from one pixel to another generally damage the signal-noise ratio, known under the name of dirty window screen effect, divulged for instance in the reference mentioned above. Therefore, different methods have been developed to reduce or suppress such variations in order to harmonise the gain.

The invention concerns an imaging device comprising a photodetector matrix based on a CMOS technology, particularly suited to spectrometry, especially for atomic emission techniques, such as for example ICP, SPARK or GDS.

The invention also concerns a spectroscopy system and an imaging method with the above advantages.

To this end, the invention relates to an imaging device comprising a photodetector line-column matrix, each of the photodetectors having a CMOS-type pixel and an amplifier with a gain.

According to the invention, the device comprises gain control means, capable of fixing the gains individually for each of the photodetectors.

Thus, instead of harmonising the gains as in the known devices, the differential gain between the photodetectors is, conversely, processed in order to choose each of them in an appropriate manner.

Preferably, the control means are provided to adjust the gains in relation to the intensities detected by these photodetectors.

Thus, useful zones of a light beam can be selected, in particular of a spectrally spread beam, without taking the other zones into account. The intensities measured in certain useful zones can also be amplified with high gain, when these intensities are small with respect to those measured in other zones.

In another advantageous embodiment, the control means are foreseen to fix the gains before all the light beam measurements.

The imaging device according to the invention provides the advantages related to CMOS-based imaging devices, i.e.:

non-destructive playback, with the possibility of accumulating loads without saturation for intense emission lines,

random access, which authorises direct selection of the pixels targeted and therefore enables to reduce the measuring time,

low noise level.

These advantages are added the capacity of increasing the dynamic range thanks to individual gain control, whereas each photodetector constitutes a complete unit in itself. Thus, the times can be managed independently on the various pixels, by a simple management and without interference among the different photodetectors.

The line-column term must not be understood as limiting the matrix to a particular shape, for example square, rectangular, ovoid, . . . , but is introduced to delineate reference axes within the said matrix, since the said axes lie in a preferred perpendicular mode and are substantially perpendicular to one another.

In advantageous embodiments, taken individually or in combination:

the matrix is composed of at least 256 pixels on one column and at least 100 pixels on one line,

the width w of the photodetectors ranges between 3 μ and 25 μ.

By ‘width’ of a photodetector is meant the dimension in a direction perpendicular to addressing lines with which the photodetectors are linked.

The invention also relates to spectroscopy system comprising a device according to the invention, foreseen to receive a spectrally spread light beam, whereas spectral spreading is oriented along the columns. In other words, the lower section of the spectrum is located at the beginning of the column and the higher section of the spectrum at the end of the said column. Within the framework of the invention, the spreading may be oriented along the lines.

The invention also concerns an imaging method in which a light beam is sent to a photodetector matrix, whereas each of the photodetectors includes a CMOS-type pixel and an amplifier with a gain.

According to the invention, the gains are fixed individually for each of the photodetectors.

This method differs from those known, in which the gains of all the photodetectors are fixed so that they are as close as possible to a reference value.

In an advantageous embodiment, the gains are adjusted in relation to the intensities detected by the photodetectors.

Preferably, the light beam is spread spectrally.

The invention also concerns the application of the spectroscopy system of the invention or of the imaging method that implements a spectrally spread light beam from the atomic emission, preferably selected among an ICP, SPARK or GDS technique.

The invention will be illustrated and understood better by means of an embodiment and an implementation mode that are not limiting, with reference to the appended figures on which:

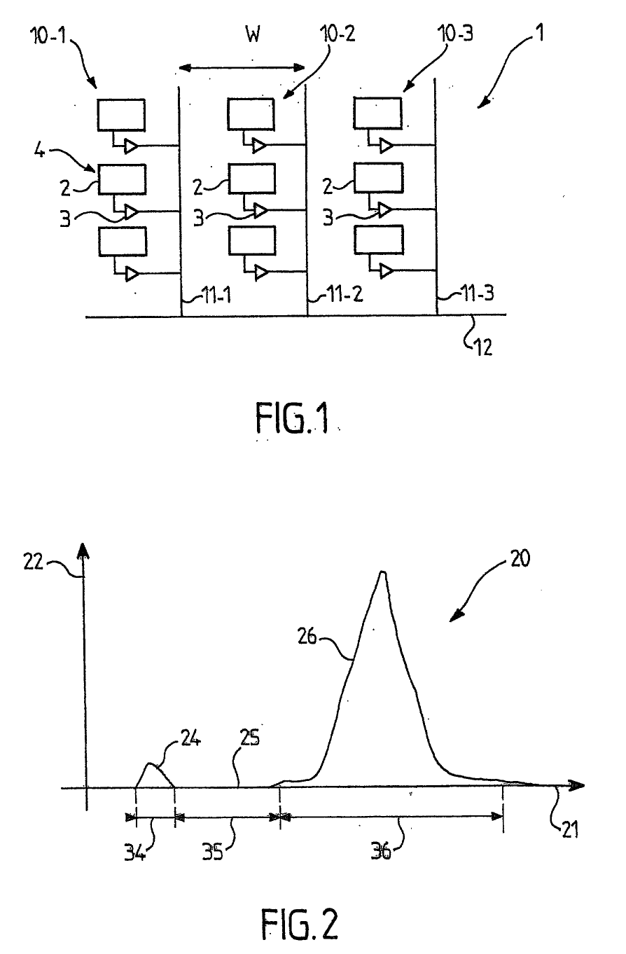

FIG. 1 represents a portion of a photodetector matrix of an imaging device according to the invention and

FIG. 2 shows a spectral graph (intensity in relation to the wavelength) processed with an imaging device according to the invention.

An imaging device comprises a matrix 1 of photodetectors 4 distributed in columns 10, such that the columns 10-1, 10-2 and 10-3 represented on FIG. 1. Each of the columns 10 is associated with an addressing line 11, referred to respectively as 11-1, 11-2 and 11-3 for the columns 10-1, 10-2 and 10-3, whereas the addressing lines 11 are connected to a central line 12.

Each of the photodetectors 4 comprises a pixel 2 associated with an individual amplifier 3. The photodetectors 4 exhibit a width w, in a direction perpendicular to that of the addressing lines 11.

The amplifiers 3 generate gains that are variable according to photodetectors 4. In a first embodiment, the amplifiers 3 generate gains fixed initially. The matrix 1 is then designed in relation to the gains requested.

In another embodiment, the imaging device also comprises gain control means, capable of acting on the amplifiers 3 in order to fix individually the corresponding gains. This realisation, which is more complex, enables to adapt the device 1 to the beams measured.

In operation, a spectrally spread light beam is sent to the matrix 1 of photodetectors 4, for example in the direction perpendicular to the addressing lines 11. The light beam received has a spectral graph 20 (FIG. 2), providing the intensity (axis 22) in relation to the wavelength (axis 21), which exhibits for example peaks 24 with small height, quasi flat sections 25 and high peaks 26. It is also possible to distinguish zones 34, 35 and 36 corresponding respectively to the different levels of intensity (24, 25 and 26) of the graph 20. Each of these zones 34, 35 or 36 covers one or several photodetectors 4.

The gains of the photodetectors 4 are selected in relation to the corresponding zones 34, 35 or 36. Thus, if the peaks 24 with small height (with a pre-set threshold level) are considered interesting, high gains for the zones 34 are selected advantageously. The zones 35 corresponding to quasi-flat sections do not require any measurement, so that the gain can be fixed arbitrarily to 0, without taking into account information from the corresponding photodetectors. For the zones 36 corresponding to high peaks, relatively low gains suffice.

By selecting the gains in such an appropriate manner, very good resolution can be obtained with a reduced measuring time.

In the embodiment where the gains are all fixed at the start, the interesting zones of the spectral graph considered and the necessary amplifying level must be known initially. Conversely, in the embodiment where the gains are controlled in relation to the intensity, these gains are adjusted according to the beams detected.

1. An imaging device comprising a line-column matrix (1) of photodetectors (4), each of the photodetectors (4) having a CMOS-type pixel (2) and an amplifier (3) with a gain,
characterised in that it comprises gain control means, capable of fixing the gains individually for each of the photodetectors (4).

2. An imaging device according to claim 1, characterised in that the said control means are provided for adjusting the said gains in relation to the intensities detected by the said photodetectors (4).

3. An imaging device according to any of claims 1 or 2, characterised in that the said matrix (1) comprises at least 256 pixels on a column and at least 100 pixels on a line.

4. An imaging device according to any of claims 1 to 3, characterised in that the width w of the photodetectors (4) ranges between 3 μ and 25 μ.

5. A spectroscopy system comprising a device according to any of claims 1 to 4, intended for receiving a spectrally spread light beam, whereas spectral spreading is oriented along the columns.

6. An imaging method in which a light beam is sent to a line-column matrix (1) of photodetectors (4), whereas each of the photodetectors (4) includes a CMOS-type pixel (2) and an amplifier (3) with a gain, characterised in that the gains are fixed individually for each of the photodetectors (4).

7. An imaging method according to claim 6, characterised in that the said gains are adjusted in relation to the intensities detected by the said photodetectors (4).

8. An imaging method according to one of claims 6 or 7, characterised in that the light beam is spectrally spread.

9. An application of the spectroscopy system according to claim 5 or of the imaging method according to claim 8 with atomic emission, preferably selected among an ICP, SPARK or GDS technique.
